(19) United States
(12) Patent Application Publication
(10) Pub. No.: US 2008/0290396 A1
(43) Pub. Date: Nov. 27, 2008

(54) SEMICONDUCTOR MEMORY

(76) Inventors: Yasuhiko MATSUNAGA, Yokohama-shi (JP); Yuji Takeuchi, Yokohama-shi (JP); Takashi Shigeoka, Fujisawa-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/125,546

(22) Filed: May 22, 2008

(30) Foreign Application Priority Data
May 24, 2007 (JP) 2007-138127

(51) Int. Cl. H01L 29/00

(52) U.S. Cl. 257/316; 257/E29.001

(57) ABSTRACT

A semiconductor memory according to an aspect of this invention comprises a semiconductor substrate which includes a memory cell array region and an interconnect line region adjoining the memory cell array region, memory cells which are provided in the memory cell array region, contact plugs which are provided in the interconnect line region, and control gate lines which are provided so as to extend from the interconnect line region to the memory cell array region and which connect the contact plugs with the memory cells, wherein the control gate lines provided in the memory cell array region include metal silicide and the control gate lines provided in the interconnect line region include no metal silicide at any part of the interconnect line region.

### CROSS-REFERENCE TO RELATED APPLICATIONS

This application is based upon and claims the benefit of priority from prior Japanese Patent Application No. 2007-138127, filed May 24, 2007, the entire contents of which are incorporated herein by reference.

### BACKGROUND OF THE INVENTION

1. Field of the Invention

This invention relates to a semiconductor memory, and more particularly to the structure of a control gate line (a word line).

2. Description of the Related Art

A nonvolatile semiconductor memory, such as a flash memory, has been installed in a wide variety of electronics devices.

The memory cell array of a flash memory is composed of a plurality of memory cells. Around the memory cell array, there are provided various peripheral circuits for controlling the memory cell array, including the control gate line and select gate line drivers.

Generally, a polycide structure where a polysilicon film and a metal silicide film are stacked one on top of the other has been used as a control gate line (word line) structure for connecting a memory cell to a control gate line/select gate line driver. The technique for applying the polycide structure to all of the control gate lines has been disclosed (e.g., refer to Jpn. Pat. Appln. KOKAI Publication No. 2007-276666).

Until now, tungsten silicide (WSi₂), which is easy to form into a film and process, has been used as a metal silicide film for control gate lines.

In recent years, metal silicide whose resistivity is lower than that of WSi₂, such as cobalt silicide (CoSi₂), titanium silicide (TiSi₂), or nickel silicide (NiSi₂), has been proposed as a new control gate line material to decrease the resistance of the control gate line further to suppress the delay of the transmission of pulses (data) caused by parasitic capacitance. However, there is a problem: CoSi₂ or the like has a low resistivity, but cannot be processed by reactive ion etching (RIE) techniques.

Therefore, each of these metal silicides is formed by depositing a metal film on a polysilicon film and then heat-treating the resulting film, thereby solid-phase-reacting the polysilicon film with a metal film.

As described above, when a metal silicide layer constituting the control gate lines has been formed, if a write/erase operation is carried out repeatedly, a leakage path (hereinafter, referred to as an inter-control-gate-line short) might occur between adjacent control gates. The cause for this can be considered as follows.

When the entire surface of the interlayer insulating film covering the polysilicon is etched back for the silicidation of polysilicon, a void develops in a place where the insulating film has been buried poorly. In the void, minute quantities of metal ions remain.

Then, when a write voltage (e.g., 20V) is applied to the selected control gate line in a write operation, if a midpoint potential (e.g., 8V) is applied to a control gate line adjacent to the selected control gate line, an electric field is generated between the adjacent control gate lines. The electric field moves metal ions.

As a result of the movement of metal ions, a current leakage path is formed at the interface of the interlayer insulating film covering the control gate lines, which causes an inter-control-gate-line short.

Furthermore, a lot of inter-control-gate shorts occur at the interface between the interconnect line region in which contact plugs are provided and the memory cell array region.

The reason for this may be that the underlying structure of the interconnect line region differs from that of the memory cell array region.

More specifically, the interconnect line region differs from the memory cell array region in the underlying structure, causing a step between the two regions. The step causes the two regions to differ from each other in lithography, making the line width of the control gate lines in the interconnect line region less than that of the control gate lines in the memory cell array region. As a result, the distance between adjacent control gate lines in the interconnect line region becomes greater.

Therefore, a void formed in the interlayer insulating film gets larger at the step part of the interconnect line region, permitting a lot of metal ions to remain. On the other hand, since the distance between control gate lines is smaller, the electric field between adjacent control gate lines becomes weaker than that of the memory cell array region.

It is conceivable that the inter-control-gate-line short depends on both the electric field between control gate lines and the concentration of remaining metal ions. The probability of shorts occurring increases at the step part at the interface between the interconnect line region and memory cell array region.

### BRIEF SUMMARY OF THE INVENTION

According to an aspect of the invention, there is provided a semiconductor memory comprising: a semiconductor substrate which includes a memory cell array region and an interconnect line region adjoining the memory cell array region; memory cells which are provided in the memory cell array region; contact plugs which are provided in the interconnect line region; and control gate lines which are provided so as to extend from the interconnect line region to the memory cell array region and which connect the contact plugs with the memory cells, wherein the control gate lines provided in the memory cell array region include metal silicide and the control gate lines provided in the interconnect line region include no metal silicide at any part of the interconnect line region.

According to another aspect of the invention, there is provided a semiconductor memory comprising: a semiconductor substrate which includes a memory cell array region and an interconnect line region adjoining the memory cell array region; memory cells which are provided via a gate insulating film above the semiconductor substrate in an active area of the memory cell array region; an isolation insulating film which is buried in the surface layer of the semiconductor substrate in the interconnect line region; dummy cells which are provided between the memory cell array region and the isolation insulating film; and control gate lines which are provided via an inter-gate insulating film on the memory cells, the dummy cells, and the isolation insulating film, wherein the control gate lines have a polysilicon film on the inter-gate insulating film in the memory cell array region and the interconnect line region, a metal silicide film is provided on the polysilicon film in the memory cell array region, and the metal silicide film is not provided on the polysilicon film at the interface between the dummy cells and the isolation insulating film.

According to still another aspect of the invention, there is provided a semiconductor memory comprising: a semiconductor substrate which includes a memory cell array region and an interconnect line region adjoining the memory cell array region; memory cells which are provided in the memory cell array region; contact plugs which are provided in the interconnect line region; and control gate lines which are provided so as to extend from the interconnect line region to the memory cell array region and which connect the contact plugs with the memory cells, wherein the control gate lines provided in the memory cell array region include metal silicide and the control gate lines provided in the interconnect line region include no metal silicide.

### BRIEF DESCRIPTION OF THE SEVERAL VIEWS OF THE DRAWING

FIG. 1 is a block diagram showing the configuration of a flash memory;

FIG. 2 is a layout chart showing the structure of a memory cell array region and its periphery;

FIG. 3 is a layout chart showing the structure of the memory cell array region and its periphery;

FIG. 4 is a plan view showing the structure of a memory cell array region and its vicinity in a first embodiment of the invention;

FIG. 5 is a sectional view taken along line V-V of FIG. 4;

FIG. 6 is a sectional view taken along line VI-VI of FIG. 4;

FIG. 7 is a sectional view taken along line VII-VII of FIG. 4;

FIG. 8 is a plan view to explain one of the manufacturing processes in the first embodiment;

FIG. 9 is a sectional view taken along line IX-IX of FIG. 8;

FIG. 10 is a plan view to explain one of the manufacturing processes in the first embodiment;

FIG. 11 is a sectional view taken along line XI-XI of FIG. 10;

FIG. 12 is a sectional view taken along line XII-XII of FIG. 10;

FIG. 13 is a plan view to explain one of the manufacturing processes in the first embodiment;

FIG. 14 is a sectional view taken along line XIV-XIV of FIG. 13;

FIG. 15 is a sectional view taken along line XV-XV of FIG. 13;

FIG. 16 is a sectional view taken along line XVI-XVI of FIG. 13;

FIG. 17 is a plan view to help explain one of the manufacturing processes in the first embodiment;

FIG. 18 is a sectional view taken along line XVIII-XVIII of FIG. 17;

FIG. 19 is a sectional view taken along line XIX-XIX of FIG. 17;

FIG. 20 is a sectional view taken along line XX-XX of FIG. 17;

FIG. 21 is a plan view showing the structure of a memory cell array region and its vicinity in a second embodiment of the invention;

FIG. 22 is a sectional view taken along line XXII-XXII of FIG. 21;

FIG. 23 is a plan view to explain one of the manufacturing processes in the second embodiment;

FIG. 24 is a sectional view showing a modification of the embodiments of the invention; and

FIG. 25 is a sectional view showing another modification of the embodiments of the invention.

### DETAILED DESCRIPTION OF THE INVENTION

### 1. Overview

An embodiment of the invention relates to the structure of a control gate line (or a word line) of a nonvolatile semiconductor memory.

A control gate line is connected to the gate electrode of a memory cell provided in a memory cell array region. The control gate line is drawn into an interconnect line region adjoining the memory cell array region and is connected to a contact plug for connecting with a driver circuit.

In the embodiment of the invention, the control gate line is characterized by having a portion which includes no metal silicide in a part where the odds are high that a short circuit between control gate lines in the interconnect line region will develop.

In the embodiment, to prevent a specific part of the control gate line from including metal silicide, etching back done on the interlayer insulating film covering polysilicon acting as a control gate electrode in the memory cell array region is not performed in a specific part of the interconnect line region in the process of causing the polysilicon film to solid-phase-react with the metal material for silicidation.

This prevents the polysilicon film serving as a control gate line from being silicided in the specific part of the interconnect line region because the polysilicon film is covered with the interlayer insulating film. As a result, the polysilicon film includes no metal silicide.

With the above structure, since the interlayer insulating film in the specific part of the interconnect line region is not etched back, no void occurs in the interlayer insulating film in the part. Therefore, it is possible to suppress the stay of metal ions in the metal material (e.g., cobalt (Co)) for forming a metal silicide layer.

Furthermore, since a region where no void occurs can be formed, it is possible to sever a void between the memory cell array region and the interconnect line region and therefore suppress the movement of metal ions.

Accordingly, with the embodiment, the probability of control gate line shorts caused by the remaining metal ions occurring can be decreased.

### 2. Embodiments

### (1) First Embodiment

First, a nonvolatile semiconductor memory to which a first embodiment of the invention is applied will be explained using a flash memory as an example.

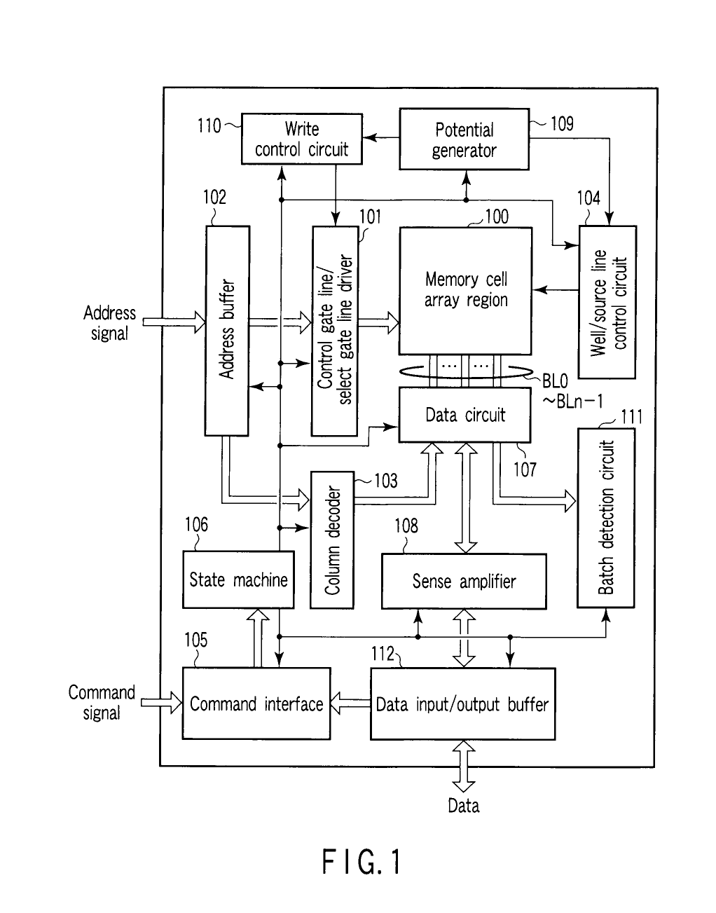

FIG. 1 is a block diagram of the main part of a memory chip of a flash memory according to the first embodiment.

A memory cell array region 100 includes a plurality of memory cells and select gate transistors.

A control gate line/select gate line driver 101 is connected to control gate lines and select gate lines extending from the memory cell array region 100. The control gate line/select gate line driver 101 drives the control gate lines and select gate lines to access a memory cell selected on the basis of an address signal from an address buffer 102.

On the basis of the address signal from the address buffer 102, a column decoder 103 selects a column in the memory cell array region 100 and drives the selected bit line.

The overall operation of the memory chip is controlled by a command interface circuit 105 and a state machine 106 on the basis of a control signal from an external unit (e.g., a host microcomputer). According to the operation mode (write, read, or erase mode) of the flash memory, each of a well/source line control circuit 104, a data circuit 107, a sense amplifier 108, a potential generator 109, a write control circuit 110, a batch detection circuit 111, a data input/output circuit 112 is controlled.

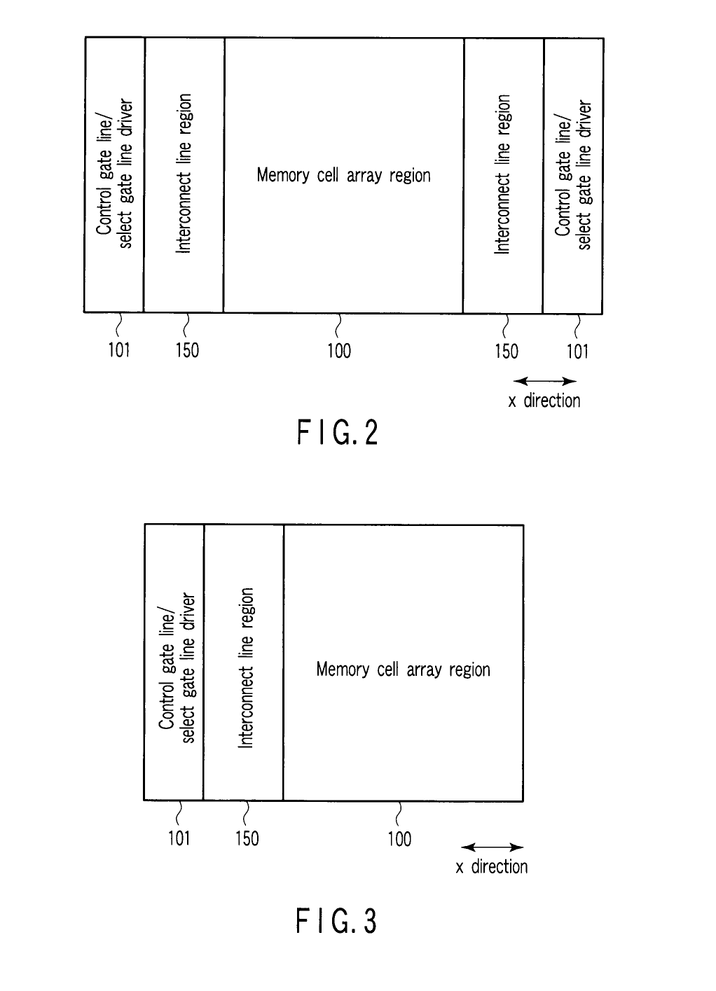

FIGS. 2 and 3 show the positional relationship between the control gate line/select gate line driver 101 and interconnect line region 150 provided around the memory cell array region 100.

In the example of FIG. 2, the control gate line/select gate line driver 101 is provided on either side of the memory cell array region 100. In the example of FIG. 3, the control gate line/select gate line driver 101 is provided at one end of the memory cell array region 100.

The peripheral circuits, including the memory cell array region 100 and control gate line/select gate line driver 101, differ in wiring pitch. For this reason, the interconnect line region 150 for converting the wiring pitch is provided between the memory cell array region 100 and the control gate line/select gate line driver 101.

Hereinafter, the first embodiment will be explained using a NAND flash memory as an example. The first embodiment is not restricted to a NAND flash memory. For instance, it may be applied to a NOR, AND, or 2- or 3-transistor flash memory.

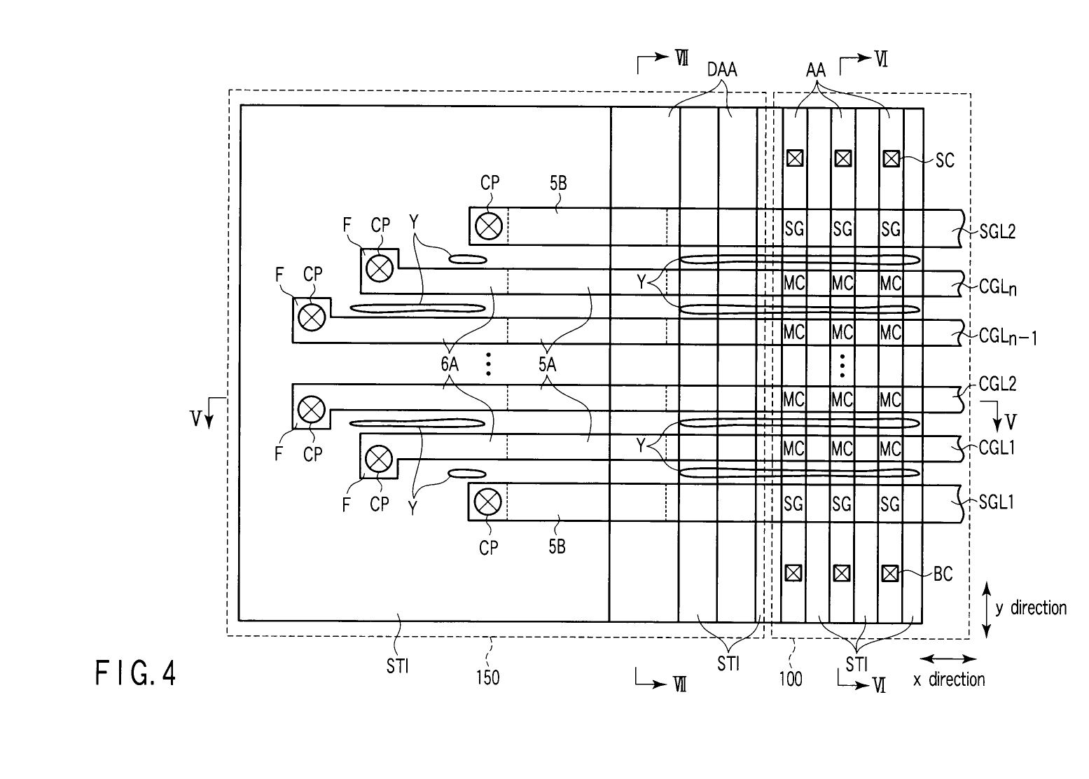

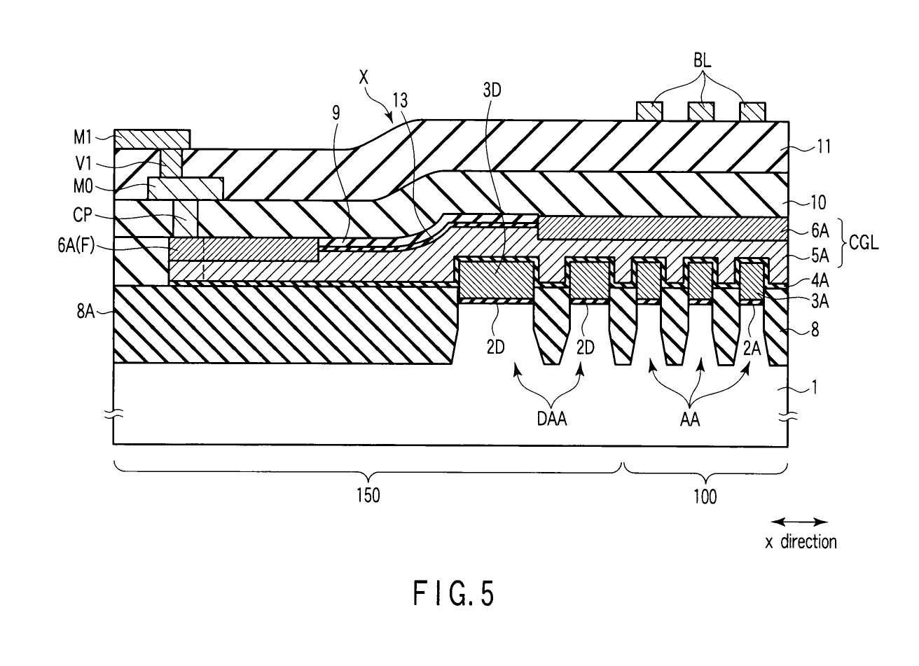

Using FIGS. 4 to 7, the structure of the memory cell array region 100 and that of the interconnect line region 150 will be explained.

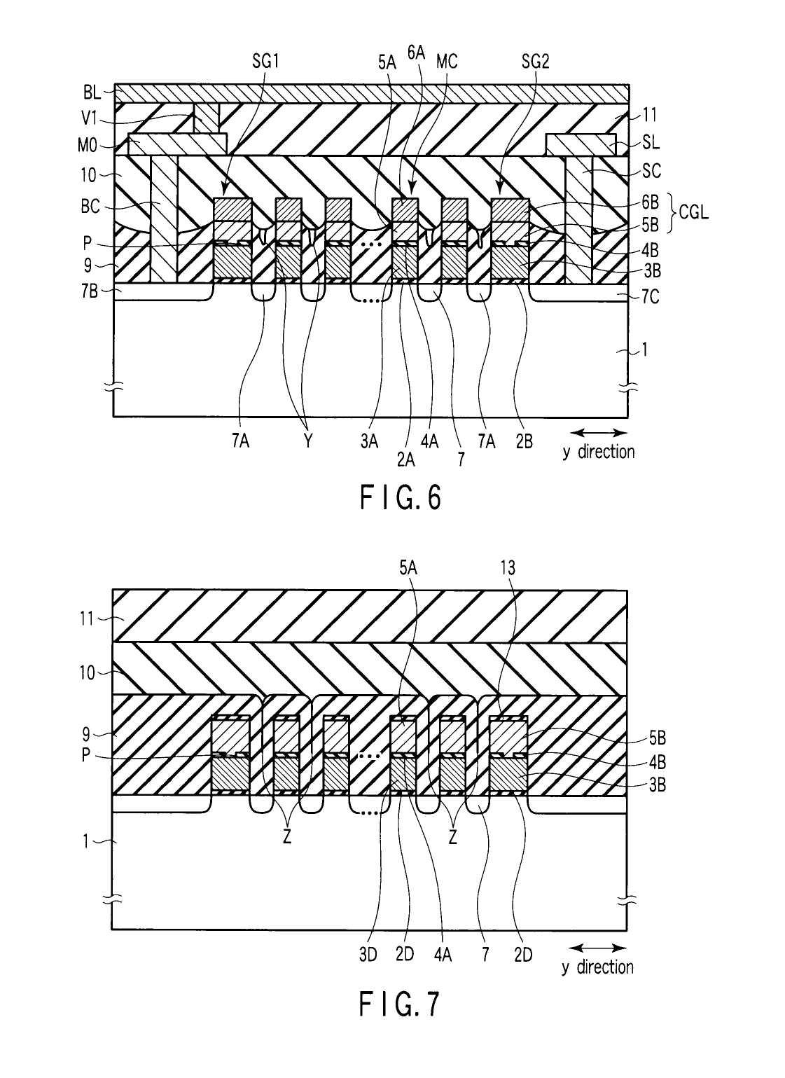

FIG. 4 is a plan view showing the structure of the memory cell array region 100 and interconnect line region 150 in the first embodiment. FIG. 5 is a sectional view taken along line V-V of FIG. 4. FIG. 6 is a sectional view taken along line VI-VI of FIG. 4. FIG. 7 is a sectional view taken along line VII-VII of FIG. 4. In the first embodiment, for simplicity, only one end of the memory cell array region 100 and the interconnect line region 150 provided next to the one end are shown.

As shown in FIGS. 4 to 7, a semiconductor substrate 1 includes the memory cell array region 100 and the interconnect line region 150 provided next to the memory cell array region 100. In the memory cell array region 100, a plurality of active areas AA surrounded by isolation areas STI are provided in a specific direction (the y-direction in FIG. 4) at the surface of the semiconductor substrate 1. In each of the active area AA, a plurality of memory cells MC and a plurality of select gate transistors SG are provided.

In the isolation areas STI which separate the active areas AA, isolation insulating film 8 which has, for example, a shallow trench insulation (STI) structure, is buried.

In the interconnect line region 150, no memory cell is provided and an isolation insulating film 8A whose dimension (width) in the x-direction is greater than that of the isolation insulating film 8 is buried in the semiconductor substrate 1. The isolation insulating layer 8A is an underlying layer. On the other hand, in the memory cell array region 100, gate electrodes 3A, 3B are underlying.

In the interconnect line region 150, a dummy active area DDA in which dummy cells not functioning as storage elements are to be formed is provided between the isolation insulating film 8A and memory cell array region 100. The dimension in the x-direction of the dummy active area DAA is designed to be greater than the dimension in the x-direction of the active area AA in which memory cells are to be provided.

A plurality of control gate lines CGL1 to CGLn are provided in the memory cell array region 100 and interconnect line region 150.

Control gate lines CGL1 to CGLn (i.e., n lines) are provided in such a manner that they extend in the x-direction and adjoin in the y-direction at specific intervals. At the intersections of the active areas AA in the memory cell array region 100 and the control gate lines CGL1 to CGLn, a plurality of memory cells MC are connected to the control gate lines CGL1 to CGLn in a one-to-one correspondence.

Two select gate lines SGL1, SGL2 are provided along the control gate lines CGL1 to CGLn in the memory cell array region 100 and interconnect line region 150 so as to sandwich the n control gate lines CGL1 to CGLn between them. At the intersections of the active areas AA in the memory cell array region 100 and the select gate lines SGL1, SGL2, a plurality of select gate transistors SG are connected to the select gate lines SGL1, SGL2.

The control gate lines CGL1 to CGLn are connected to fringes F provided in the interconnect line region 150. Each of the fringes F is connected to a metal layer M1 serving as an interconnect line via a contact plug CP, an intermediate metal layer M0, and a via contact V1. The control gate lines may be connected directly to the contact plugs CP without providing any fringe F.

Similarly, each of the select gate lines SGL1, SGL2 is connected to a metal layer M1 serving as an interconnect line via a contact plug CP, an intermediate metal layer M0, and a via contact V1. In the first embodiment, as shown in FIG. 5, the control gate electrode CGL of a memory cell MC is shared by elements adjoining in the x-direction and functions as one of the control gate lines CGL1 to CGLn.

As shown in FIG. 5, because of the difference in the underlying structure, the top surface of the control gate electrode CGL on the isolation insulating film 8A is made lower than that of the control gate line CGL of the memory cell array region 100. With this difference of elevation, a step part with a step X is formed in the control gate line CGL (and interlayer insulating films 10, 11 formed in it upper part) near the interface between the dummy active area DAA and isolation insulating film 8A.

Furthermore, the structure of the control gate line CGL near the interface between the dummy active area DAA and isolation insulating film 8A differs from that of the control gate line CGL of the memory cell array region 100 and that of the control gate line CGL near the area where the contact plug CP is formed. That is, each of the control gate line CGL of the memory cell array region 100 and the control gate line CGL near the area where the contact plug CP is formed is composed of a polysilicon film 5A and a metal silicide film 6A, whereas the control gate line CGL in a silicidation block area near the interface between the dummy active area DAA and isolation insulating film 8A is composed of only a polysilicon film 5A, with the result that a metal silicide film 6A is not formed. The silicidation block area is formed so as to include a step part formed near the interface between the dummy active area DAA and isolation insulating layer 8A.

FIG. 6 shows one NAND cell unit, more specifically, a plurality of memory cells MC (i.e., n cells) connected in series and select gate transistors SG1, SG2 connected to one and the other end of the series combination respectively.

As shown in FIG. 6, each of the memory cells MC is, for example, a stacked-gate metal-insulator-semiconductor (MIS) transistor which uses a floating gate electrode 3A composed of a polysilicon film as a charge storage layer.

The floating gate electrode 3A is provided on a gate insulating film 2A formed at the surface of the semiconductor substrate 1. Control gate electrodes 5A, 6A are stacked one on top of the other above the floating gate electrode 3A via an inter-gate insulating film 4 formed on the floating gate electrode 3A.

A control gate electrode CGL is composed of a polysilicon film 5A and a metal silicide film 6A made of metal silicide, such as cobalt silicide (CoSi₂).

Therefore, each of the control gate lines CGL1 to CGLn in the memory cell array region 100 has a so-called polycide structure composed of the polysilicon film 5A and metal silicide film 6A. As described above, each of the control electrodes CGL is shared by a plurality of memory cells MC adjoining in the x-direction, which enables them to function as the control gate lines CGL1 to CGLn.

Furthermore, a plurality (i.e., n) memory cells MC adjoining in the y-direction are connected in series, sharing a source/drain diffused layer 7.

One end (drain side) and the other end (source side) of the series-connected memory cells MC are provided with select gate transistors SG1, SG2, respectively, each of which is connected to an adjacent memory cell MC via a source/drain diffused layer 7A.

Since the select gate transistors SG1, SG2 are formed in the same process as that of the memory cells MC, they are stacked-gate MIS transistors. A first gate electrode 3B composed of a polysilicon film formed together with the floating gate electrode 3A is provided on a gate insulating film 2B formed at the surface of the semiconductor substrate 1. A polysilicon film 5B is connected to the first gate electrode 3B via an opening P formed in an inter-gate insulating film 4B. On the polysilicon film 5B, a metal silicide film 6B is formed. The gate electrodes 3B, 5B, 6B of the select gate transistors SG1, SG2 composed of the gate electrode 3B, polysilicon film 5B, and metal silicide film 6B are shared by a plurality of select gate transistors adjoining in the x-direction, which causes them to function as select gate lines SGL1, SGL2.

The source/drain diffused layer 7B of the select gate transistor SG1 is connected to a first metal layer M0 via a bit line contact BC. The first metal layer M0 is connected to a bit line BL via a via contact V1.

Moreover, the source/drain diffused layer 7C of the select gate transistor SG2 is connected to a source line SL via a source line contact SC.

In FIG. 6, an interlayer insulating film 9 is formed on the semiconductor substrate 1 between the gate electrodes of the memory cells MC, the semiconductor substrate 1 between the memory cells MC and the select gate transistors SG1, SG2, and the semiconductor substrate in which the source/drain diffused layer 7B, 7C are formed. The interlayer insulating film 9 is formed so that the surface of the semiconductor substrate 1 may be almost as high as the interface between the polysilicon films 5A, 5B and the metal silicide films 6A, 6B. On the interlayer insulating film 9, an interlayer insulating film 10 is formed so as to cover the metal silicide films 6A, 6B. On the interlayer insulating film 10, an interlayer insulating film 11 is formed. On the interlayer insulating film 11, bit lines BL are formed.

FIG. 7 shows a cross-section structure of the dummy active area DAA taken along line VII-VII of FIG. 4.

As shown in FIG. 7, the cross-section structure in the y-direction of the dummy active area DAA is similar to the cross-section structure in the y-direction of the active area AA in the memory cell array region 100.

Dummy layers (polysilicon films) 3B, 3D formed together with the floating gate electrode 3A are provided on an insulating film 2D formed on the surface of the semiconductor substrate 1. The dummy layer 3B does not function as a charge storage layer. The film thickness of the insulating film 2D is greater than that of the gate insulating film 2A of the memory cell MC. The insulating film 2D has a film thickness of, for example, 40 nm.

Above the dummy layers 3B, 3D, polysilicon films 5A, 5B acting as the control gate lines CGL1 to CGLn and select gate lines SG1, SG2 are provided via inter-gate insulating films 4A, 4B, respectively. On the polysilicon films 5A, 5B, a mask material 13 explained later is provided. As shown in FIG. 7, on the polysilicon films 5A, 5B of the interconnect line region 150, the metal silicide films 6A, 6B formed on the polysilicon films 5A, 5B of the memory cell array region 100 are not formed.

In FIG. 7, on the semiconductor substrate 1 between the gate electrodes of the dummy cells composed of the dummy layer 3A, polysilicon films 5A, 5B, and dummy layers 3B, 3D, an interlayer insulating film 9 is formed. The interlayer insulating film 9 is formed so as to cover the mask material 13 formed on the dummy cell. On the interlayer insulating film 9, interlayer insulating films 10, 11 are formed sequentially.

As described above, the dimension in the x-direction of the dummy active area DAA is greater than the dimension in the x-direction of the active area AA in which memory cells MC are provided.

The first embodiment is characterized in that the control gate lines CGL1 to CGLn extending in the x-direction include no metal silicide in a specific part of the interconnect line region 150.

As shown in FIGS. 4 to 7, the part including no metal silicide of the control gate lines CGL1 to CGLn are provided so as to include, for example, a region (a step part) with a step X in the interconnect line region 150.

Of the control gate lines, the part including no metal silicide are formed by neither etching back the interlayer insulating film 9 which covers a part of the interconnect line region 150 nor siliciding the polysilicon layer 5A in siliciding the control gate lines in the memory cell array region 100.

In the silicidation block area, the structure of the control gate lines is a single-layer structure of the polysilicon layer 5A. In the interconnect line region 150 outside the silicidation block area, each of the control gate lines CGL1 to CGLn has a polycide structure as in the memory cell array region 100. It is desirable that the parts (fringes F) where the control gate lines CGL1 to CGLn are connected to contact plugs should have a structure including metal silicide to reduce parasitic resistance to the contact plugs CP.

In the memory cell array region 100, the pitch of the control gate lines CGL1 to CGLn is narrower as a result of miniaturization. Therefore, the interlayer insulating film is buried poorly between the narrower-pitch control gate lines CGL1 to CGLn, with the result that, for example, a part (seam) Z where a bond between the insulating films is poor develops as a result of the insulating films just being in touch with each other as shown in FIG. 7.

Then, to silicide the polysilicon film 5A by solid-phase reaction, the interlayer insulating film 9 is etched back, with the result that the parts where seams Z have developed are etched excessively and voids V appear as shown in FIG. 6.

In the voids, metal ions, such as Co, at the time of the formation of a metal silicide film remain, which causes inter-control-gate short circuits particularly at the step parts.

However, in the first embodiment, a silicidation block area is provided in a region where an inter-control-gate short circuit is liable to occur, such as a step part, and the interlayer insulating film 9 in the area is not etched back.

Since the interlayer insulating film 9 is not etched back in the silicidation block area, such a void Y as is formed in the memory cell array region 100 is not formed. Accordingly, since no void occurs in the silicidation block area including step parts, the concentration of remaining metal ions becomes smaller.

Furthermore, between the memory cell array region 100 and interconnect line region 150, the void V can be severed with the silicidation block area. This prevents the metal ions remaining in the memory cell array region 100 and interconnect line region 150 from moving between the two regions and being supplied to the silicidation block area.

Therefore, the occurrence of a leakage path between control gate lines caused by metal ions can be suppressed. Consequently, the probability of inter-control-gate-line short circuits occurring can be decreased.

(b) Manufacturing Method

Using FIGS. 4 to 20, a manufacturing method according to the first embodiment will be explained.

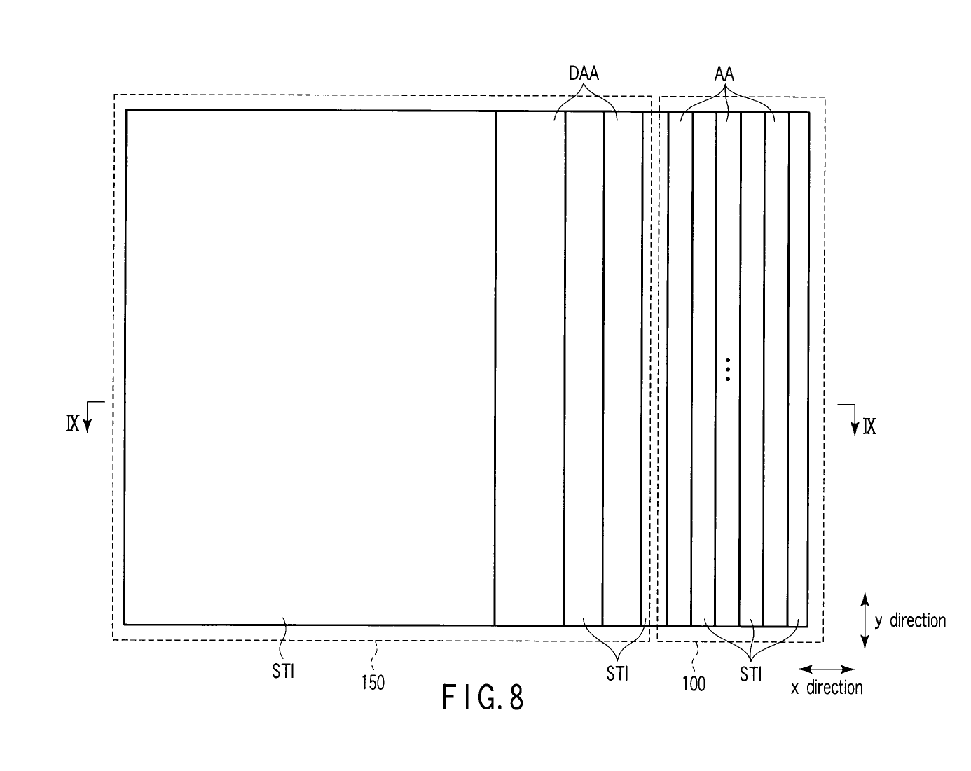

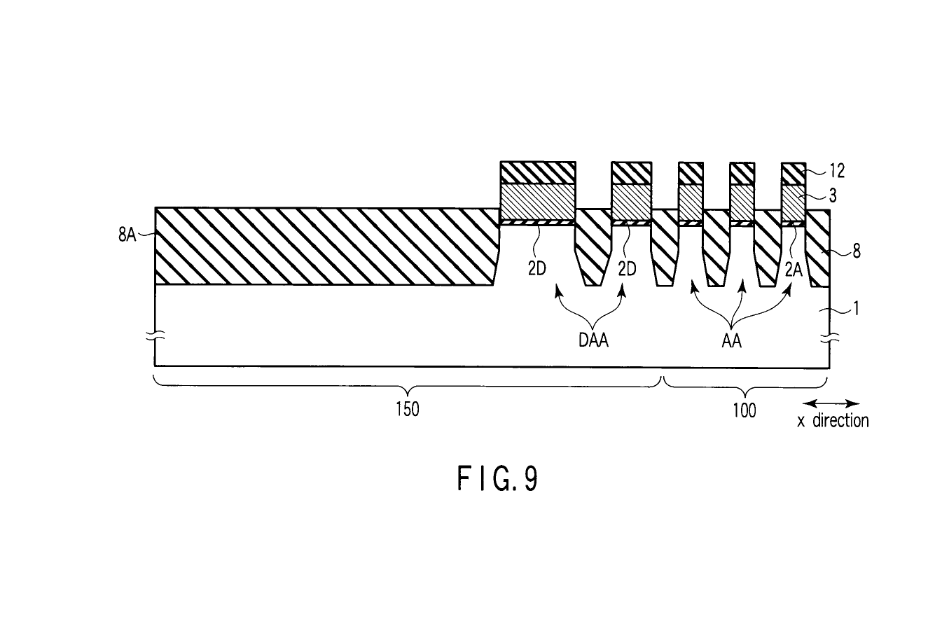

First, using FIGS. 8 and 9, one process of the manufacturing method in the first embodiment will be explained.

FIG. 8 is a plan view to explain one of the manufacturing processes in the first embodiment. FIG. 9 is a sectional view taken along line IX-IX of FIG. 8.

As shown in FIGS. 8 and 9, on a semiconductor substrate 1, a gate insulating film 2A and an insulating film 2D are formed by, for example, a thermal oxidation method.

Next, a polysilicon film 3 serving as the floating gate electrode of a memory cell and a first mask film (e.g., a silicon nitride film) are formed sequentially by, for example, chemical vapor deposition (CVD) techniques.

Then, in the memory cell array region 100, a plurality of isolation trenches are made in the semiconductor substrate 1 by, for example, RIE techniques so that a plurality of active areas AA of a specific dimension in the x-direction may be formed.

At the same time, isolation trenches are made in the interconnect line region 150. At the end of the interconnect line region on the memory cell array region side, dummy active areas DAA are formed. The dimension in the x-direction of the dummy active areas DAA is designed to be greater than the dimension in the x-direction of the active areas AA.

Then, in the memory cell array region 100 and interconnect line region 150, insulating films 8, 8A are formed in the isolation trenches.

Thereafter, the isolation insulating film 8 is etched until the side surface in the x-direction of the polysilicon film 3 (3A, 3B, 3D) is exposed. In addition, the film thickness of the insulating film 2D formed in the dummy area DAA is greater than the film thickness of the gate insulating film 2A. For example, the film thickness of the insulating film 2D is 40 nm.

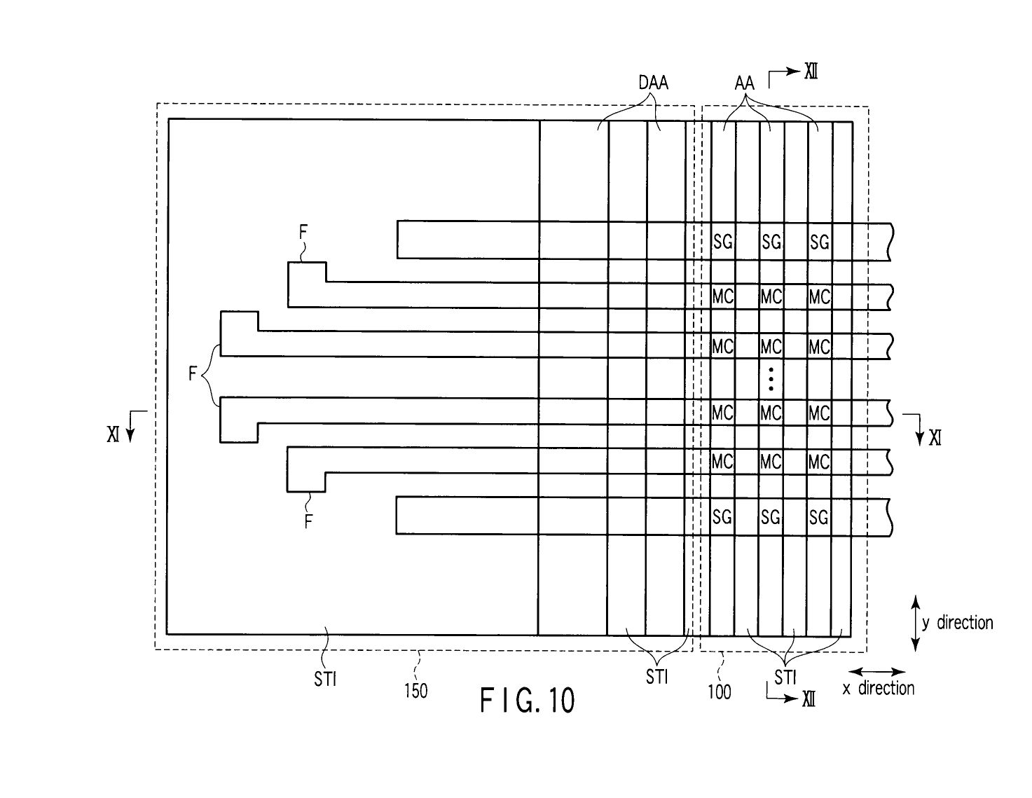

Next, using FIGS. 10 to 12, the manufacturing process following FIGS. 8 and 9 will be explained.

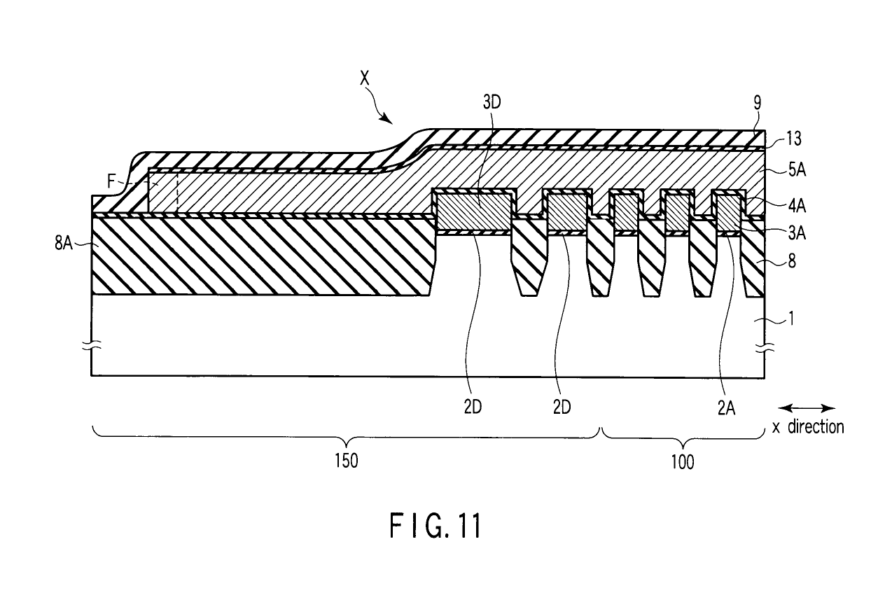

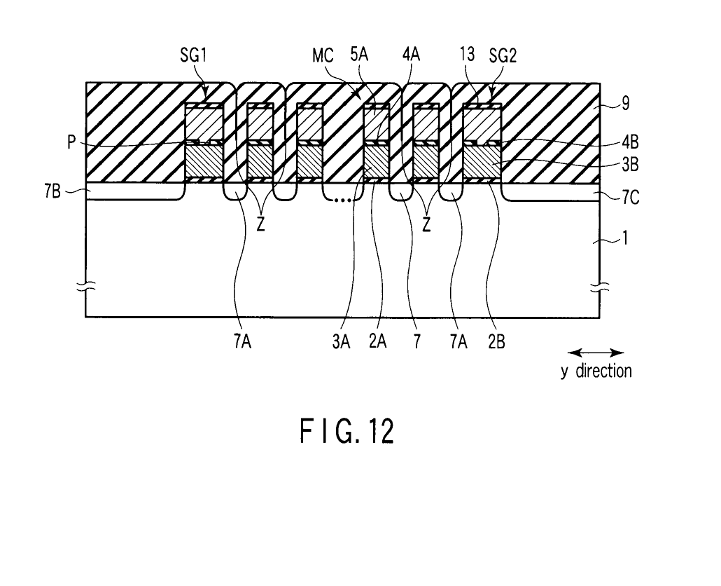

FIG. 10 is a plan view to help explain one of the manufacturing processes in the first embodiment. FIG. 11 is a sectional view taken along line XI-XI of FIG. 10. FIG. 12 is a sectional view taken along line XII-XII of FIG. 10.

After the first mask film is removed, inter-gate insulating films 4A, 4B are formed on the entire surface of the memory cell array region 100 and interconnect line region 150 so as to cover the top and side surfaces of the polysilicon films 3A, 3B, 3D and the top surfaces of the isolation insulating films 8, 8A. Then, in a select gate transistor formation region, an opening is formed in the inter-gate insulating film 4B. Each of the inter-gate insulating films 4A, 4B is composed of, for example, a single layer film of a silicon oxide film, a silicon nitride film, or a high dielectric film, such as HfSiON or Al₂O₃, or a multilayer film of those films.

Then, polysilicon films 5A, 5B serving as control gate electrodes and a second mask film 13 (e.g., a silicon nitride film) are deposited sequentially on the inter-gate insulating films 4A, 4B in the memory cell array region 100 and interconnect line region 150 by, for example, CVD techniques. At this time, in the select gate transistor formation region, an opening P is formed in the inter-gate insulating film 4B.

Next, for the memory cells to have a desired gate length, the second mask film 13 is patterned by, for example, photolithographic techniques. Then, a polysilicon film serving as control gate electrodes and floating gate electrodes and an inter-gate insulating film are etched, followed by the gate processing.

As a result, the memory cells MC are formed each of which is composed of a floating gate electrode film 3A, an inter-gate insulating film 4A, and a control gate electrode 5A. At the same time, select gate transistors SG1, SG2 composed of the first and second gate electrodes 3B, 5B are formed. The first and second gate electrodes 3B, 5B are connected with each other through the opening P formed in the gate insulating film 4B.

Furthermore, at the time of the gate processing, the mask layer 13 is patterned to form, for example, a closed loop pattern in the memory cell array region 100 and interconnect line region 150. Then, a certain part of the closed loop pattern is severed in the interconnect line region 150, with the result that a fringe F composed of the polysilicon film 5A is formed in the interconnect line region 150 at the same time the gate is processed.

The gate of a memory cell may be processed by the microfabrication technique for processing an underlying layer using the sidewalls.

Thereafter, with the stacked-gate electrode formed by the gate processing as a mask, source/drain diffused regions 7, 7A, 7B, and 7C are formed in the semiconductor substrate 1 in a self-aligning manner.

Furthermore, a first interlayer insulating film 9 (e.g., a TEOS film) covering the gate electrodes of the memory cells and the select gate transistors is formed by, for example, CVD techniques.

As shown in FIG. 11, since the underlying structure of the memory cell array region 100 differs from that of the interconnect line region 150 near the interface between the memory cell array region 100 and interconnect line region 150, for example, on the dummy active area DAA, a step X develops. As a result, height of the top of the interlayer insulating film 9 differs between the memory cell array region 100 and interconnect line region 150.

Moreover, as shown in FIG. 12, seams Z develop in the first interlayer insulating film 9 between the control gate lines CGL1 to CGLn.

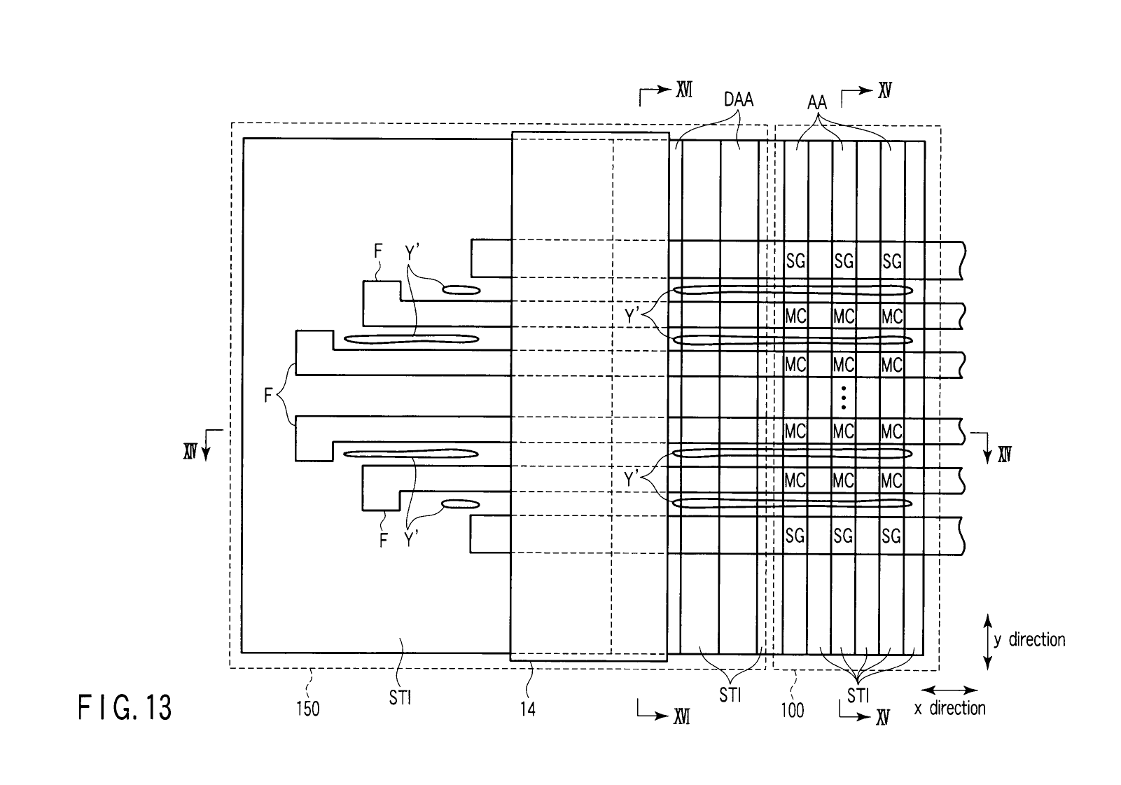

Next, using FIGS. 13 to 16, the manufacturing process following FIGS. 10 and 12 will be explained. FIG. 13 is a plan view to explain one of the manufacturing processes in the first embodiment.

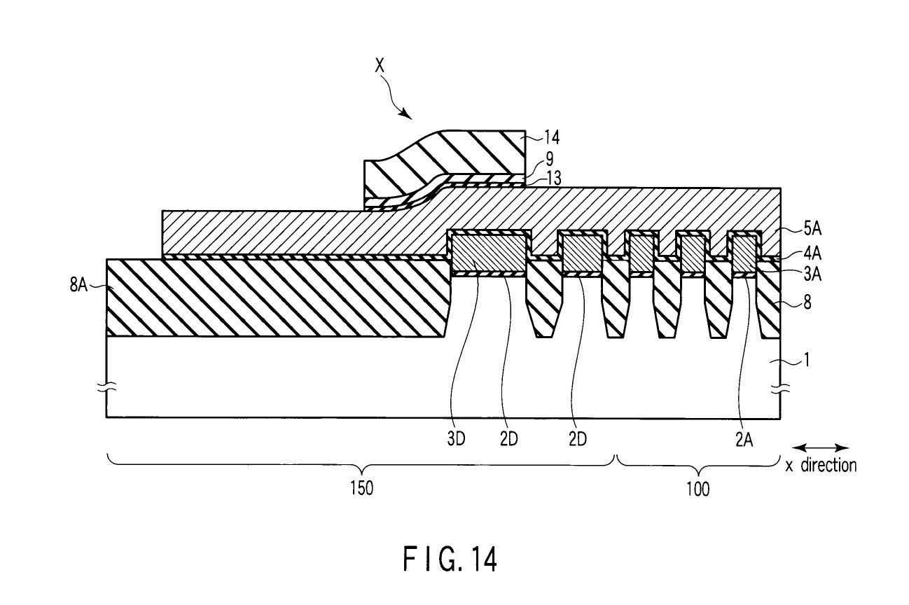

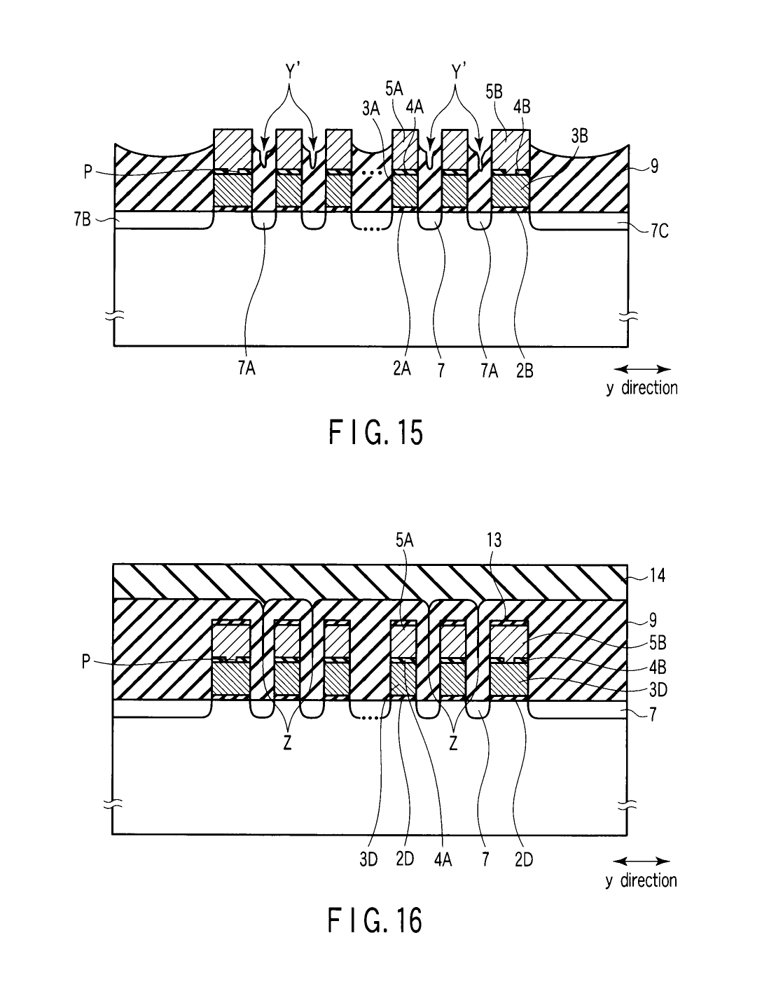

FIG. 14 is a sectional view taken along line XIV-XIV of FIG. 13. FIG. 15 is a sectional view taken along line XV-XV of FIG. 13. FIG. 16 is a sectional view taken along line XVI-XVI of FIG. 13.

As shown in FIGS. 13 to 16, to prevent the interlayer insulating film 9 from being etched back, a resist mask 14 is formed by, for example, photolithographic techniques on the interlayer insulating film 9 in the area (silicidation block area) where the control gate lines are not silicided.

The silicidation block area is provided so as to include the step part having a step X in the dummy active area DAA of the interconnect line region 150. It is desirable that the silicidation block area should be provided not only in the step part but also in an area where the probability of inter-control-gate shorts occurring is high.

Thereafter, the interlayer insulating film 9 is etched back by, for example, RIE techniques.

Then, as shown in FIG. 15, the interlayer insulating film 9 is etched in a region not covered with the resist mask 14, such as the memory cell array region 100. At this time, grooves Y′ are made as a result of the seams in the interlayer insulating film 9 being expanded by excessive etching between adjacent control gate electrodes 5A (control gate lines CGL1 to CGLn).

On the other hand, as shown in FIG. 16, in the area covered with the resist mask 14, that is, the silicidation block area, the interlayer film 9 is not etched back and remains covered with the polysilicon film 5A serving as a control gate line. Therefore, in the silicidation block area, the parts of the seams Z are not etched, which prevents the expansion of the seams as found in the memory cell array region 100.

Furthermore, as shown in FIG. 13, the silicidation block area is provided, which enables the groove Y′ to be severed in the region between the memory cell array region 100 and interconnect line region 150.

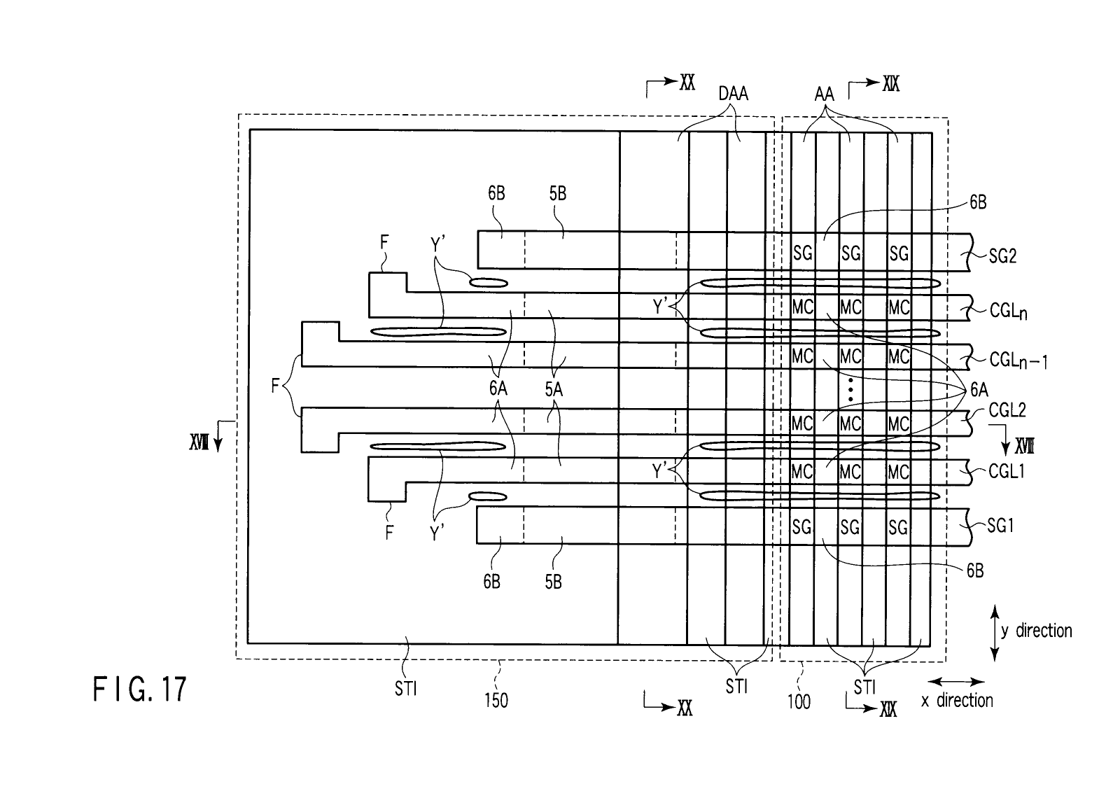

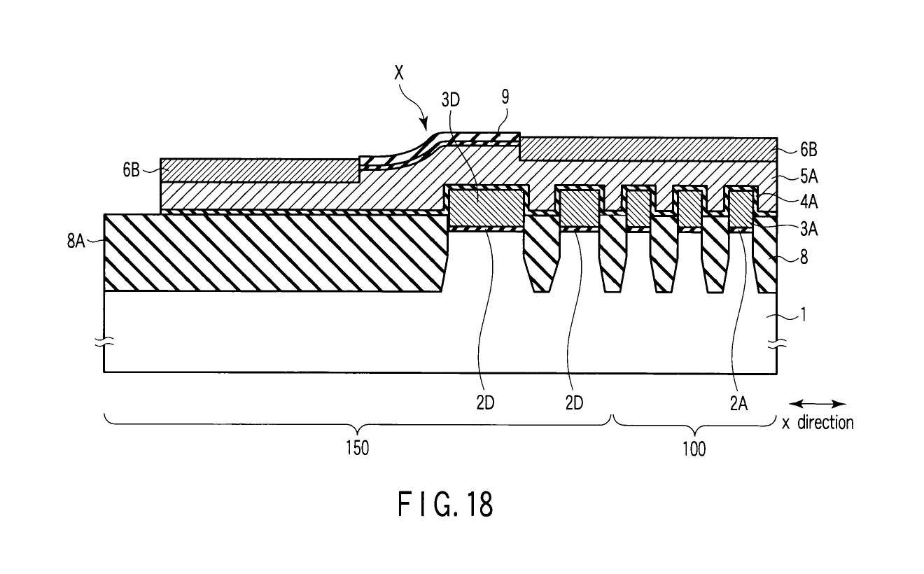

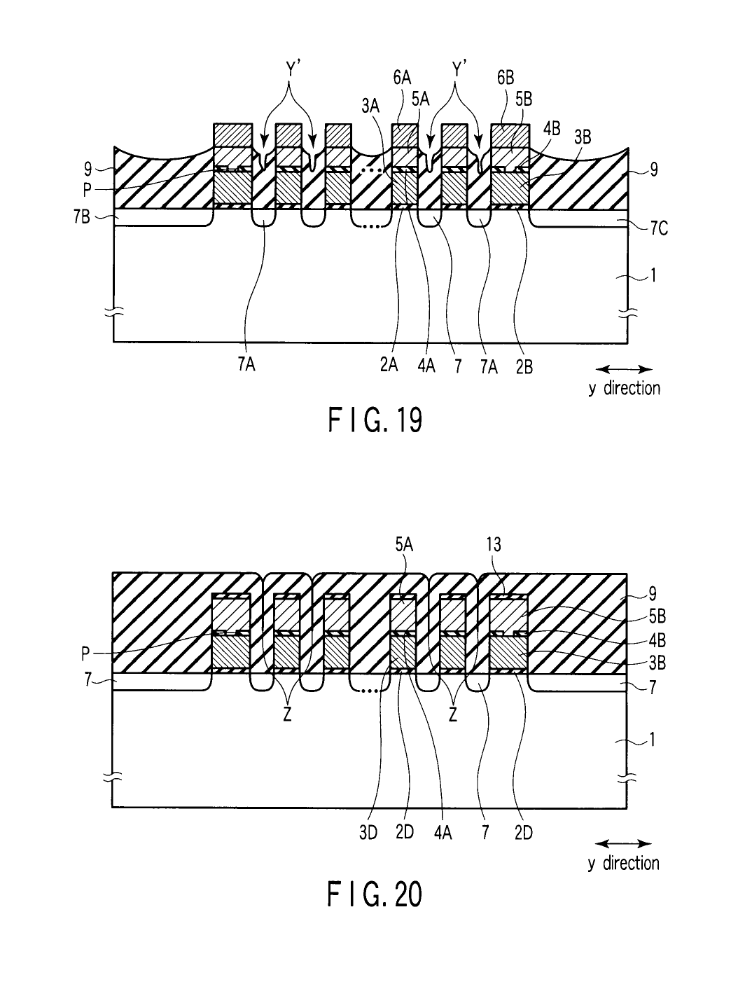

Next, using FIGS. 17 to 20, the manufacturing process following FIGS. 13 and 16 will be explained. FIG. 17 is a plan view to explain one of the manufacturing processes in the first embodiment. FIG. 18 is a sectional view taken along line XVIII-XVIII of FIG. 17. FIG. 19 is a sectional view taken along line XIV-XIV of FIG. 17. FIG. 20 is a sectional view taken along line XX-XX of FIG. 17.

After the resist mask is removed, for example, cobalt (Co) is deposited on the interlayer insulating film 9 and polysilicon films 5A, 5B by sputtering techniques. The embodiment of the invention is not limited to Co. For instance, nickel (Ni), titanium (Ti), or tungsten (W) may be deposited by sputtering techniques to form a metal film.

Next, the semiconductor substrate 1 is heat-treated, thereby causing the polysilicon films 5A, 5B to solid-phase-react with Co for silicidation. Thereafter, the Co not reacted with the polysilicon films 5A, 5B is removed by, for example, wet etching.

Then, as shown in FIGS. 17 to 20, gate control gate lines CGL1 to CGLn with a two-layer structure (polycide structure) of the polysilicon film 5A and a metal silicide film (e.g., CoSi₂) 6A are formed in the memory cell array region 100 and interconnect line region 150. The metal silicide film 6A is not restricted to CoSi₂. As described above, in the case of using any of the Ti, Ni, and W as metal film, the metal silicide, such as TiSi₂, NiSi₂, or WSi₂, can be formed by solid-phase reaction.

On the other hand, as shown in FIG. 20, since all of the polysilicon films 5A, 5B are covered with the interlayer insulating film 9 in the silicidation block area, the polysilicon films 5A, 5B are not silicided even if a metal material is formed on the interlayer insulating film 9. Consequently, the control gate lines in the area include no metal silicide and each have a single-layer structure of the polysilicon film 5A.

Moreover, since the interlayer insulating film 9 is not etched in this area, the seams do not expand. Consequently, no metal ion remains in the grooves in the silicidation block area.

It is desirable that polysilicon should be silicided to form a metal silicide film 6A at the fringes of the control gate lines CGL1 to CGLn in order to reduce parasitic resistance to the contact plugs formed in a subsequent process.

Thereafter, as shown in FIGS. 4 to 7, a second interlayer insulating film 10 is formed on the entire surface of the first insulating film 9. In the contact holes made in the first and second interlayer insulating films 9, 10, bit line contacts BC, source line contacts SC, and contact plugs PC are buried. The first metal layer M0 and source line SL are connected to each of the contacts. At this time, since the interlayer insulating film 10 cannot be buried completely in the grooves Y′ in the control gate lines CGL1 to CGLn in the part excluding the silicidation block area, voids Y develop.

Furthermore, a third interlayer insulating film 11 is formed on the interlayer insulating film 10. Then, via contacts V1 are buried in the contact holes made in the interlayer insulating film 11. To the via contacts V1, second metal layers M1 are connected as interconnect lines connected to the bit line BL or control gate line/select gate line drivers.

By the above processes, a flash memory of the first embodiment is formed.

As described above, with the manufacturing method of the first embodiment, each of the control gate lines in the memory cell array region 100 is composed of the polysilicon film 5A and metal silicide film 6A and has a polycide structure.

On the other hand, a specific part of the control gate lines in the interconnect line region 150 are composed of only the polysilicon film 5A including no metal silicide film. The part including no metal silicide film are a part of the control gate lines in the area where the probability of inter-control-gate shorts occurring is high, such as the area with a step X between the memory cell array region and interconnect line region.

As described above, when the part including no metal silicide layer is formed, for example, a resist mask 14 is formed on the step part, a silicidation block area is provided, and the interlayer insulating film 9 covering the polysilicon film 5A in the area is not etched back.

This prevents the seams Z in the interlayer insulating film 9 from being etched excessively in the silicidation block area, which causes no void. Consequently, the concentration of remaining metal ions, such as Co, in the silicidation block area decreases.

Furthermore, the silicidation block area enables the void Y to be severed between the memory cell array region 100 and interconnect line region 150. Accordingly, the metal ions remaining in the memory cell array region 100 and interconnect line region 150 can be prevented from moving between the two regions and being supplied to the silicidation block area.

Therefore, when the write voltage is applied, the occurrence of a leakage path between control gate lines can be suppressed.

Accordingly, with the manufacturing method of the first embodiment, it is possible to provide a flash memory where the probability of inter-control-gate short circuits occurring has been decreased.

### (2) Second Embodiment

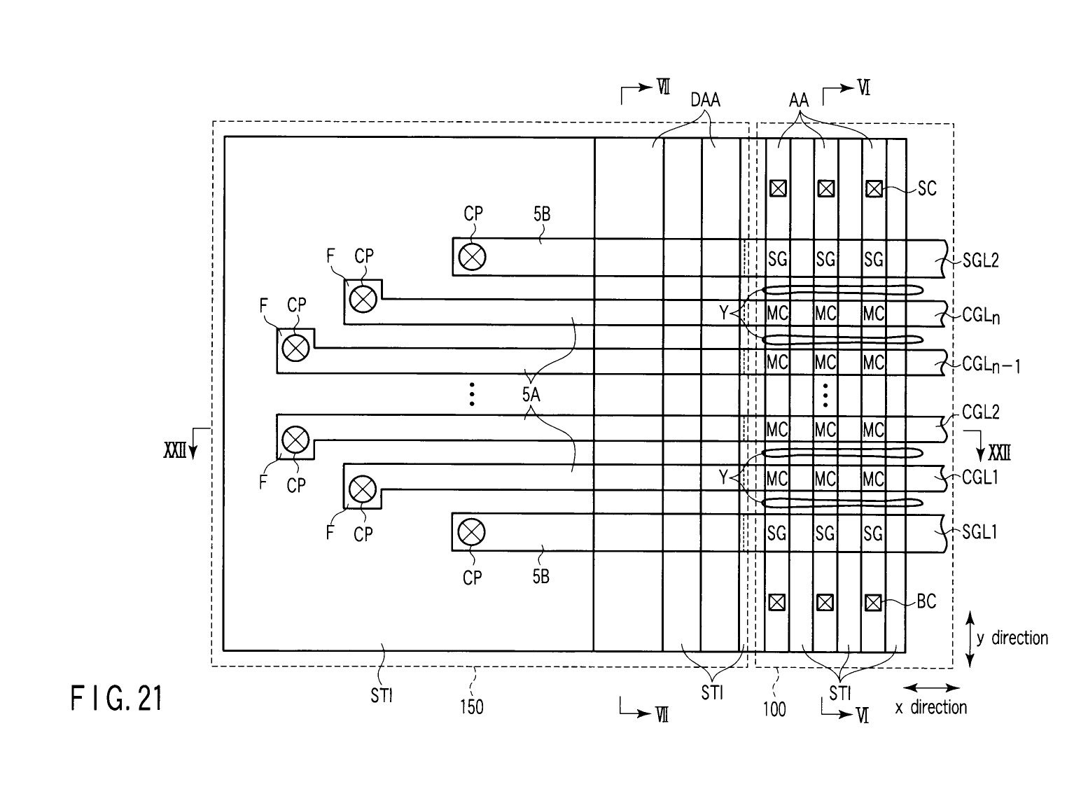

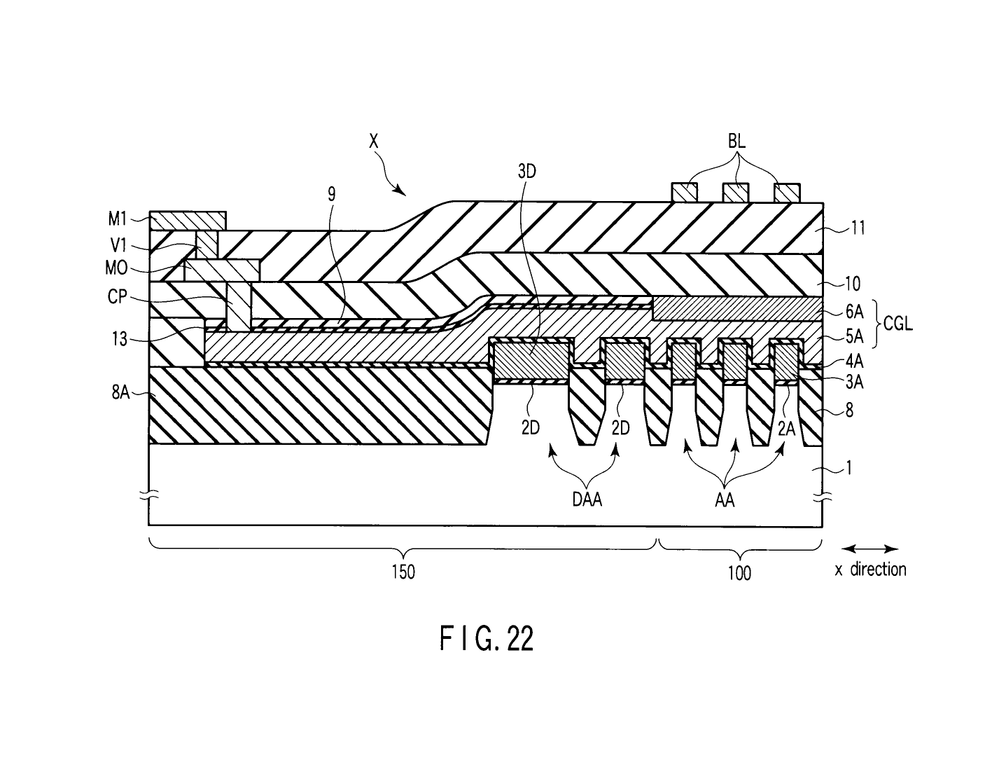

Using FIGS. 21 and 22, a second embodiment of the invention will be explained. The same parts as those in the first embodiment are indicated by the same reference numbers and a detailed explanation of them will be omitted.

Moreover, since the cross-section structure in the y-direction of the memory cell array region 100 and interconnect line region 150 is the same as that of FIGS. 6 and 7 of the first embodiment, a detail explanation will be omitted.

As shown in FIG. 21, the second embodiment is characterized in that, of the control gate lines CGL1 to CGLn connecting the memory cells MC and the contact plugs CP, all of the part of the control gate lines provided in the interconnect line region 150 include no metal silicide.

That is, the control gate lines in the interconnect line region 150 have a single-layer structure of the polysilicon layer 5A.

The structure of the control gate lines CGL1 to CGLn is formed by providing a silicidation block area in the entire interconnect line region 150 including the step part.

Accordingly, in the second embodiment, no void is formed in the whole of the interconnect line region 150.

Therefore, in the interconnect line region 150 where no void develops in the interlayer insulating film 9, a leakage path between control gate lines caused by the metal ions remaining in the void does not occur.

Consequently, the probability of inter-control-gate-line short circuits caused by metal ions occurring can be decreased further.

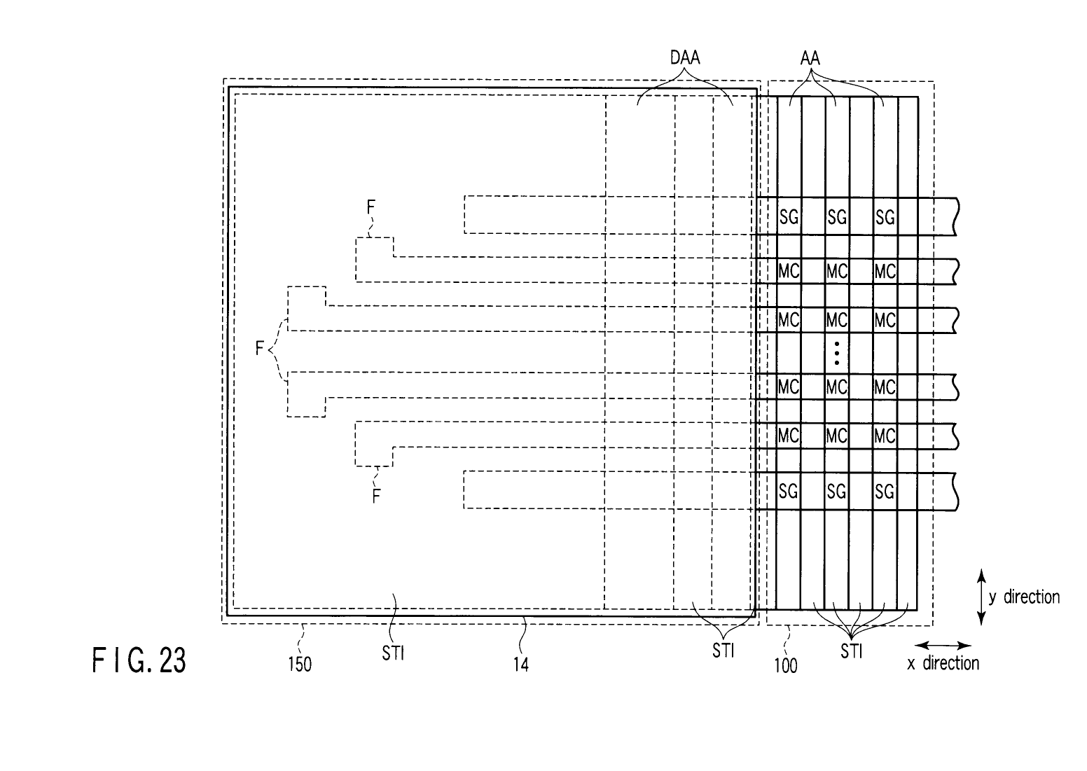

In the manufacturing method of the second embodiment, the interlayer insulating film 9 is formed in the memory cell array region 100 and interconnect line region 150 in the same process as that in the first embodiment and then the resist mask 14 is formed so as to cover the whole of the interconnect line region 150 as shown in FIG. 23 in the processes of FIGS. 13 to 16.

Then, only the interlayer insulating film 9 in the memory cell array region 100 is etched back, which prevents the polysilicon film 5A serving as the control gate lines provided in the interconnect line region 150 from being silicided. Moreover, since the interlayer insulating film 9 in the interconnect line region 150 is not etched, the seam part is also not etched and therefore a groove produced by the expansion of the seam is not formed. Accordingly, in a subsequent process, even when the interlayer insulating film 10 is formed on an interlayer insulating film 9, no void occurs between the control gate lines CGL1 to CGLn in the interconnect line region 150.

Thereafter, in the same processes as those in the first embodiment, the interlayer insulating films 10, 11, bit line contacts BC, source line contacts SC, contact plugs CP, metal layers M0, M1 is formed sequentially.

Consequently, with the manufacturing method of the second embodiment, it is possible to provide a flash memory where the probability of occurrence of inter-control-gate-line short circuits has been reduced.

### (3) Modification

In the first and second embodiments, the structure of the control gate lines CGL1 to CGLn in the memory cell array region 100 is polycide structure which a metal silicide film is stacked on a polysilicon film, producing a.

However, the invention is not limited to the structure, may be provided that a part or all of the control gate lines in the interconnect line region 150 include no metal silicide. For instance, as shown in FIG. 24, the control gate lines in the memory cell array region 100 may have a single-layer structure of each of the metal silicides 6A, 6B. That is, the control gate lines may have a full silicide structure.

In this case, in the processes of FIGS. 17 to 20 in the first embodiment, the polysilicon film serving as the control gate lines in the memory cell array region 100 are solid-phase-reacted with, for example, Co, thereby siliciding the whole of the polysilicon film.

On the other hand, a silicidation block area is provided in the interconnect line region 150 in the siliciding process, thereby preventing a part or all of the control data lines provided in the interconnect line region from being silicided.

This makes it possible to cause the control gate lines in the interconnect line region 150 to have a part including no metal silicide.

Accordingly, as in the first and second embodiments, the probability of inter-control-gate-line short circuits occurring can be decreased.

Moreover, in the first and second embodiments, the memory cells provided in the memory cell array region have used the floating gate electrodes as charge storage layers.

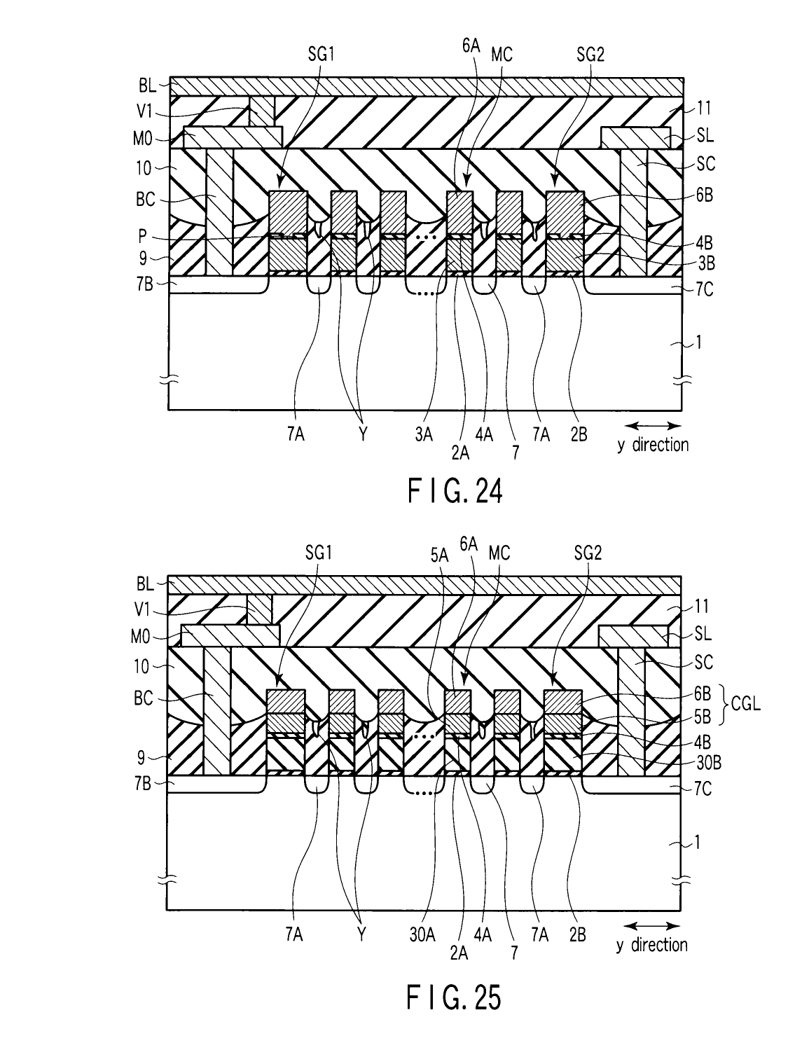

However, the embodiments of the invention is not restricted to the structure of the memory cells connected to the control gate lines, maybe provided a part or all of the control gate lines in the interconnect line region 150 include no metal silicide. For instance, as shown in FIG. 25, the memory cells may have a metal-oxide-nitride-oxide-semiconductor (MONOS) structure where insulating films 30A, 30B, such as silicon nitride films, are used as charge storage layers.

### 3. Others

While in the embodiments, a nonvolatile semiconductor memory (flash memory) has been used, the invention is not limited to this. The invention may be applied to another semiconductor memory, such as a dynamic random access memory (DRAM) or a static random access memory (SRAM). In that case, too, the same effects as those of the embodiments are obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory comprising:
a semiconductor substrate which includes a memory cell array region and an interconnect line region adjoining the memory cell array region;
memory cells which are provided in the memory cell array region;
contact plugs which are provided in the interconnect line region; and
control gate lines which are provided so as to extend from the interconnect line region to the memory cell array region and which connect the contact plugs with the memory cells,
wherein the control gate lines provided in the memory cell array region include metal silicide and the control gate lines provided in the interconnect line region include no metal silicide at any part of the interconnect line region.

2. The semiconductor memory according to claim 1, wherein the control gate lines provided in the memory cell array region have a single-layer structure of metal silicide.

3. The semiconductor memory according to claim 1, wherein the part including no metal silicide of the control gate lines have a single-layer structure of polysilicon.

4. The semiconductor memory according to claim 1, wherein the metal silicide includes any one of cobalt, nickel, titanium, and tungsten.

5. The semiconductor memory according to claim 1, wherein each of the memory cells includes
a gate insulating film which is provided at the surface of the semiconductor substrate;
a floating gate electrode which is provided on the gate insulating film;
an inter-gate insulating film which is provided on the floating gate electrode, and
a control gate electrode which is provided on the inter-gate insulating film and acts as the control gate.

6. The semiconductor memory according to claim 1, wherein each of the memory cells includes
a gate insulating film which is provided at the surface of the semiconductor substrate;
an insulating film which is provided on the gate insulating film and acts as a charge storage layer;
an inter-gate insulating film which is provided on the charge storage layer, and
a control gate electrode which is provided on the inter-gate insulating film and acts as the control gate line.

7. A semiconductor memory comprising:
a semiconductor substrate which includes a memory cell array region and an interconnect line region adjoining the memory cell array region;
memory cells which are provided via a gate insulating film above the semiconductor substrate in an active area of the memory cell array region;
an isolation insulating film which is buried in the surface layer of the semiconductor substrate in the interconnect line region;
dummy cells which are provided between the memory cell array region and the isolation insulating film; and
control gate lines which are provided via an inter-gate insulating film on the memory cells, the dummy cells, and the isolation insulating film,
wherein the control gate lines have a polysilicon film on the inter-gate insulating film in the memory cell array region and the interconnect line region,
a metal silicide film is provided on the polysilicon film in the memory cell array region, and
the metal silicide film is not provided on the polysilicon film at the interface between the dummy cells and the isolation insulating film.

8. The semiconductor memory according to claim 7, wherein the control gate lines provided in the memory cell array region have a single-layer structure of metal silicide.

9. The semiconductor memory according to claim 7, wherein the metal silicide includes any one of cobalt, nickel, titanium, and tungsten.

10. The semiconductor memory according to claim 7, wherein the part including no metal silicide of the control gate lines are made of polysilicon.

11. The semiconductor memory according to claim 7, wherein the top surface of the control gate lines provided in the memory cell array region is designed to be higher than the top surface of the control gate lines formed on the isolation insulating film in the interconnect line region, and the control gate lines have steps between the dummy cells and the isolation insulating film.

12. The semiconductor memory according to claim 7, wherein each of the memory cells includes a floating gate electrode which is provided between the gate insulating film and the inter-gate insulating film.

13. The semiconductor memory according to claim 7, wherein each of the memory cells includes an insulating film which is provided between the gate insulating film and the inter-gate insulating film and acts as a charge storage layer.

14. The semiconductor memory according to claim 7, wherein the dimension of the dummy cells is greater than the dimension of the memory cells.

15. A semiconductor memory comprising:
a semiconductor substrate which includes a memory cell array region and an interconnect line region adjoining the memory cell array region;
memory cells which are provided in the memory cell array region;
contact plugs which are provided in the interconnect line region; and
control gate lines which are provided so as to extend from the interconnect line region to the memory cell array region and which connect the contact plugs with the memory cells,
wherein the control gate lines provided in the memory cell array region include metal silicide and the control gate lines provided in the interconnect line region include no metal silicide.

16. The semiconductor memory according to claim 15, wherein the control gate lines provided in the memory cell array region have a single-layer structure of metal silicide.

17. The semiconductor memory according to claim 15, wherein the control gate lines provided in the interconnect line region have a single-layer structure of polysilicon.

18. The semiconductor memory according to claim 15, wherein the metal silicide includes any one of cobalt, nickel, titanium, and tungsten.

19. The semiconductor memory according to claim 15, wherein each of the memory cells includes
a gate insulating film which is provided at the surface of the semiconductor substrate;
a floating gate electrode which is provided on the gate insulating film;
an inter-gate insulating film which is provided on the floating gate electrode, and
a control gate electrode which is provided on the inter-gate insulating film and acts as the control gate line.

20. The semiconductor memory according to claim 15, wherein each of the memory cells includes
a gate insulating film which is provided at the surface of the semiconductor substrate;
an insulating film which is provided on the gate insulating film and acts as a charge storage layer;
an inter-gate insulating film which is provided on the charge storage layer, and
a control gate electrode which is provided on the block insulating film and acts as the control gate line.
